(19) United States
(12) Patent Application Publication
(10) Pub. No.: US 2009/0045472 A1
(43) Pub. Date: Feb. 19, 2009

(54) Methodology for Reducing Post Burn-In Vmin Drift

(75) Inventors: Srinivasan Chakravarthi, Murphy, TX (US); Narendra Singh Mehta, Dallas, TX (US); Rajesh Khamankar, Coppell, TX (US); Ajith Varghese, Austin, TX (US); Malcolm J. Bevan, San Jose, CA (US); Tad Grider, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/837,709

(22) Filed: Aug. 13, 2007

(51) Int. Cl. H01L 29/94; H01L 21/8234

(52) U.S. Cl. 257/412; 438/238; 257/E29.345; 257/E21.616

(57) ABSTRACT

A semiconductor device includes source/drain regions formed in a substrate and having a concentration of nitrogen of at least about 5E18 cm⁻³. A gate dielectric is located over the substrate and between the source/drain regions. Gate sidewall spacers are located over said source/drain regions. A nitrogen-doped electrode including polysilicon is located over the gate dielectric. The electrode has a concentration of nitrogen therein greater than the concentration of nitrogen in the source/drain regions.

### TECHNICAL FIELD

The invention is directed, in general, to fabrication of semiconductor devices, and more specifically, to a method of reducing burn-in yield loss due to changes of minimum stable SRAM cell operating voltage, Vₘᵢₙ, during burn-in.

### BACKGROUND

Before shipping packaged semiconductor devices, the devices are typically subjected to a “burn-in” procedure. Such a procedure is designed to accelerate the failure of latent or immature defects in a device so that the part does not fail after delivery to a customer. The burn-in conditions, e.g., temperature, voltage and time, are selected to reduce the probability of later failure of delivered devices below a threshold determined by customer requirements or business judgment.

While it is preferable to cause a device to fail before shipment rather than after customer installation, such failures represent yield loss to the manufacturer. But to the extent that the cause of the failure can be identified, that information may be fed back to the manufacturing process to drive process improvement to increase the yield of later-produced devices.

At the same time that manufacturers strive for greater burn-in yield, they also engage in ongoing engineering to increase the performance and transistor density of semiconductor devices by reducing the size (“shrinking”) of transistor dimensions. Burn-in failures and the failure modes serve a key role in assessing the reliability of a process technology as it matures after a transistor shrink.

In some cases, shrinking the transistor results in the expression of a failure mode that was negligible or absent prior to the shrink. In particular, new failure modes associated with gate dielectrics with a thickness of about 1.2 nm or less are leading to burn-in yield loss in emerging technology nodes. Loss of burn-in yield results in a large loss of value due to the investment in the device at that point.

### SUMMARY

The invention provides, in one embodiment, a semiconductor device having source/drain regions formed in a substrate and having a concentration of nitrogen of at least about 5E18 cm⁻³. A gate dielectric is located over the substrate and between the source/drain regions. Gate sidewall spacers are located over the source/drain regions. A nitrogen-doped electrode including polysilicon is located over the gate dielectric, and has a concentration of nitrogen therein greater than the concentration of nitrogen in the source/drain regions.

Another embodiment is a field effect transistor (FET) including source/drain regions formed in a substrate and having a concentration of nitrogen of at least about 5E18 cm⁻³. A gate dielectric is located over the substrate and between the source/drain regions. Gate sidewall spacers are located over the source/drain regions. A nitrogen-doped electrode including polysilicon and an n-type dopant is located over the gate dielectric, and has a concentration of nitrogen therein greater than both a concentration of the n-type dopant in the electrode and the average nitrogen concentration in the source/drain.

Another embodiment is a method of manufacturing an integrated circuit. The method includes forming source/drain regions in a substrate and a gate dielectric layer over the substrate. A polysilicon layer is deposited over the gate dielectric layer. The polysilicon layer is doped with an n-type dopant and nitrogen. A portion of the polysilicon layer is removed to form an electrode between the source/drain regions. The source/drain regions and the electrode are doped with nitrogen.

### BRIEF DESCRIPTION OF THE DRAWINGS

Reference is now made to the following descriptions taken in conjunction with the accompanying drawings, in which:

FIG. 1 illustrates a transistor;

FIGS. 2A and 2B illustrate grain boundary diffusion of dopants in a polycrystalline layer;

FIGS. 3A and 3B illustrate nitrogen implantation into a polycrystalline layer;

FIG. 4 illustrates the polycrystalline layer of FIG. 3 after anneal;

FIG. 5 illustrates a transistor formed according to the invention; and

FIG. 6 illustrates a semiconductor device.

### DETAILED DESCRIPTION

In general, a MOS transistor with a lower gate resistance operates with a faster switching speed than the same transistor with a higher gate resistance. The lower gate resistance results in a lower RC delay caused by the parasitic resistance and capacitance of the gate electrode. When the gate electrode is formed from a semiconducting layer such as polysilicon, e.g., the resistivity of the electrode may be reduced by implanting a dopant therein. For this reason, in some manufacturing processes, a source/drain dopant is also implanted into the gate electrode to lower the sheet resistance thereof.

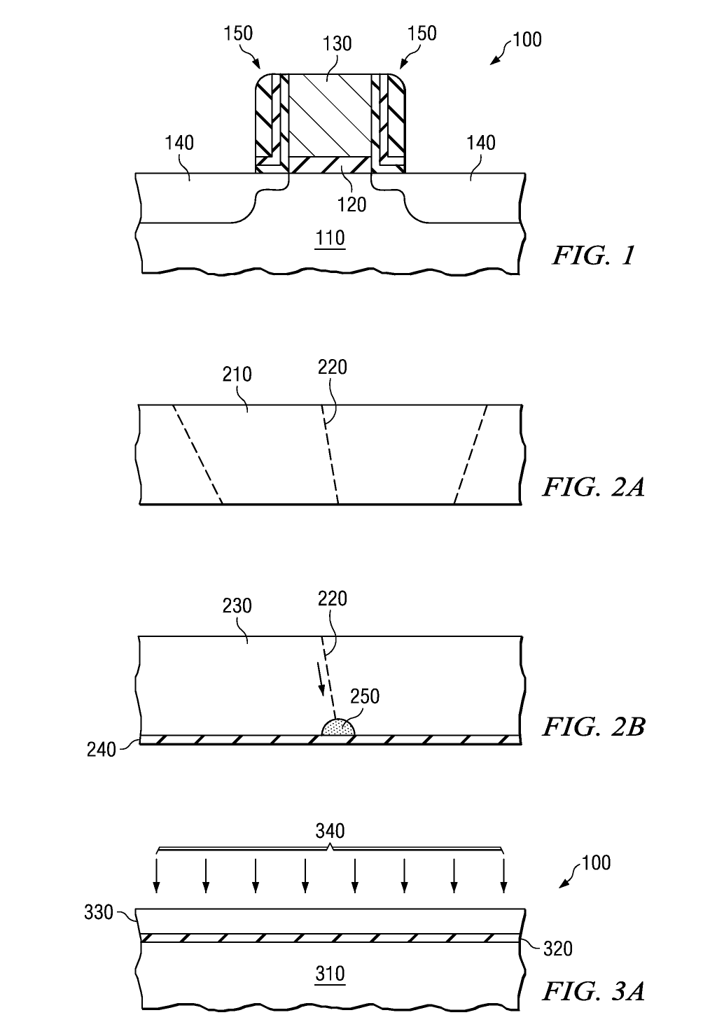

FIG. 1 illustrates a transistor 100 formed according to the invention over a semiconductor substrate 110, typically a silicon wafer. The transistor 100 includes a gate dielectric 120 and a gate electrode 130. Source/drain regions 140 include a source/drain dopant. The source/drain dopant may be an n-type or p-type dopant. An n-type dopant is a dopant that increases a concentration of mobile electrons in the substrate 110 lattice when incorporated therein. In silicon, e.g., arsenic (As) or phosphorous (P) may be used as an n-type dopant. Conversely, a p-type dopant increases a concentration of holes in the lattice. Boron (B), e.g., may be used as a p-type dopant in a silicon substrate. Sidewall spacers 150 partially block the implanting of the source/drain dopant into the source/drain regions 140.

The gate electrode 130 also includes the source/drain dopant. As described below, the electrode is exposed to a source/drain implant process, so receives a portion of the dopant implanted into the source/drain regions 140. The source/drain dopant has the effect of reducing the resistance of the gate electrode 130. However, the presence of grain boundaries in the gate electrode 130 may lead to defects that reduce device burn-in yield when the thickness of the gate dielectric 120 is below a threshold value.

FIG. 2A illustrates a gate electrode layer 210 prior to formation of a gate electrode therefrom. When the gate electrode layer 210 is formed from a polycrystalline material layer such as, e.g., polysilicon, the resulting gate electrode may include grain boundaries 220 that occur at interfaces between crystal grains of the gate material. Neighboring grains may be characterized by having a different orientation of the crystal lattice in each grain. It is thought that the interface between grains, known as a grain boundary, is characterized by lattice defects such as vacancies, dangling bonds and lattice strain. Moreover, while there may be some bonding between the grains, the density of dangling bonds in the grain boundary region is thought to be higher than in the lattice of the bulk crystal.

FIG. 2B illustrates a gate electrode 230 formed from the gate electrode layer 210 and a gate dielectric 240 thereunder. A source/drain dopant such as, e.g., As or P has been implanted by the source/drain implantation process. Without limitation by theory, it is thought that source/drain dopant atoms concentrate at the grain boundary 220. Furthermore, the dopant atoms may have a relatively high mobility along the grain boundary 220, leading to grain boundary diffusion of the dopant atoms. Under some conditions, the source/drain dopant atoms may diffuse to the gate dielectric 240 and form an impurity region 250 having a locally high concentration of the source/drain dopant atoms.

Operating characteristics of transistors having a relatively thick gate dielectric 120 are relatively insensitive to the presence of the impurity regions 250. However, when the thickness of the gate dielectric 240 is 1.2 nm or less, the long-term stability of the operating characteristics may be detrimentally affected. It is thought that the presence of an impurity region 250 creates local interface states in the gate dielectric 240 causing an increase in gate leakage paths along this region. The gate dielectric 240 then behaves less ideally and allows current to leak between the gate electrode 230 and source/drain regions.

An SRAM bitcell is typically formed with cross-coupled inverters, and depends on balanced transistor drive currents for stable operation. When current leaks from a transistor gate electrode and source/drain regions of a transistor in the bitcell, the bitcell becomes unbalanced, and the minimum reliable operating voltage of the SRAM cell, Vₘᵢₙ, may drift. When the drift exceeds a threshold value, the bitcell experience a Vₘᵢₙ failure, causing failure of the device the bitcell is a part of.

As described previously, the parasitic resistance of the gate electrode 230 may be reduced by implanting a source/drain dopant therein. But while the resistance of the gate electrode 230 may decrease as additional As or P, e.g., is implanted, the risk of forming the impurity regions 250 increases. As a result, device burn-in yield may fall. In one experiment, for example, increasing an implant dose of As in the gate electrode from about 4E14 cm⁻² to about 2E15 cm⁻² increased the drive current as desired, but resulted in an unacceptable number of post burn-in Vₘᵢₙ failures. In such cases, it may be necessary to limit the concentration of the source/drain dopant in the gate electrode 230 to reduce number or size of the impurity regions 250. But reducing the concentration of the source/drain dopant does not realize the advantage of lower gate electrode resistance.

Some transistor fabrication processes include implanting nitrogen into source/drain regions to reduce the formation of dislocations caused by source/drain dopants. The gate electrode is typically exposed during this implant process. It was discovered that a population of semiconductor devices having transistors including this nitrogen implant process exhibited a small but statistical increase of device lifetime as measured by a correlation of the Vₘᵢₙ of device SRAM cells before and after burn-in.

It was additionally discovered that this increase of lifetime was caused by the collateral implantation of nitrogen into exposed gate electrode during the source/drain nitrogen implant. However, attempts to exploit this discovery by simply increasing the implanted nitrogen dose in the gate electrode and source/drain regions failed. Transistor performance was unacceptable due to increased resistance of the source/drain regions. In some cases, this increased resistance also resulted in yield loss from an increase in lattice defects, such as dislocations, in the source/drain regions.

The invention, at least in part, recognizes that the drive current of MOS transistors can be increased without sacrificing transistor performance or burn-in yield by implanting nitrogen into the gate electrode layer 210 before forming the gate electrode 130. Thus, the concentration of nitrogen in the gate electrode 230 is increased without increasing the concentration of nitrogen in the source/drain regions and causing the associated disadvantages.

As used herein, “concentration” of a dopant in a structural element, unless otherwise qualified, refers to the average concentration of the dopant in that element. An average concentration is based on a substantially uniform distribution of the dopant in the structural element. In the case of a doped region such as a source/drain region, the physical extent of the region is defined by a surface having a source/drain dopant concentration that is about one tenth of a maximum concentration of the dopant in the source/drain region.

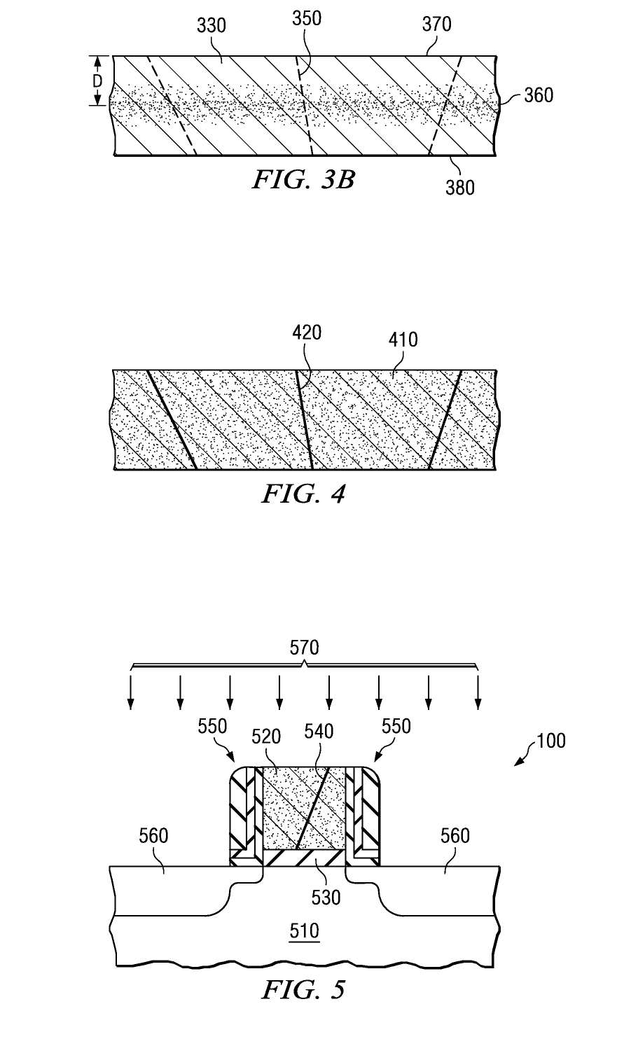

FIG. 3A illustrates the transistor 100 formed according to an embodiment of the invention at a stage of fabrication over a substrate 310. A gate dielectric layer 320 has been formed over the substrate 310, and a gate electrode layer 330 has been formed thereover. In some cases the gate dielectric layer 320 is a nitrided dielectric layer, such as silicon oxynitride. Such a layer may be formed, e.g., by remote nitrogen plasma treatment of a thermally grown oxide layer. The gate electrode layer 330 may be a polycrystalline semiconductor layer such as, e.g., polysilicon. An implant process 340 implants nitrogen into the gate electrode layer 330.

FIG. 3B illustrates a sectional view of the gate electrode layer 330 after nitrogen implantation. In general, grain boundaries 350 are present in the gate electrode layer 330 since the gate electrode layer 330 is polycrystalline. A nitrogen-rich region 360 is present with a peak concentration at a depth D below the surface of the gate electrode layer 330. In an advantageous embodiment, the peak concentration is placed about equidistant between a top surface 370 and a bottom surface 380 of the gate electrode layer 330. In this manner, subsequent thermal processing may distribute the nitrogen in the gate electrode layer 330 in a substantially homogeneous manner.

The nitrogen implant process 340 may be an ion implantation process. The nitrogen may be implanted as a monatomic (N⁺, e.g.) or diatomic (N₂⁺, e.g.) species about normal to the surface. As discussed further below, the nitrogen implant dose may be chosen based on a concentration of a source/drain dopant. In a nonlimiting example, when the gate electrode layer 330 is about 120 nm thick, N⁺ may be implanted with energy ranging from about 12 keV to about 17 keV, with about 15 keV preferred. When N₂⁺ is used, then the implant energy may range from about 25 keV to about 35 keV, with about 30 keV preferred. In one example, a dose of about 1E15 cm⁻² may be used, producing an average nitrogen concentration in the gate electrode layer 330 of about 8.3E21 cm⁻³. If a different thickness of polysilicon is used, the implant energy and dose may be adjusted accordingly.

FIG. 4 illustrates a sectional view of the gate electrode layer 330 after the implanted nitrogen dose is distributed therein to form a nitrogen-doped electrode layer 410. Distribution may be effected by a furnace diffusion process, such as 900° C. for 30 min, e.g. A portion of the nitrogen is thought to concentrate at the grain boundaries 350. The nitrogen is further thought to react with reactive sites at the grain boundaries 350 to form passivated grain boundaries 420.

Without limitation by theory, it is thought that the implanted nitrogen acts to render defects at the passivated grain boundary 420 unavailable for further interaction with source/drain dopants implanted in a later step. The presence of nitrogen in the grain boundary thus substantially reduces diffusion of the source/drain dopant along the grain boundary, reducing or eliminating the formation of the impurity regions 250. Thus, Vₘᵢₙ is stabilized and the percentage of device failures during burn-in may be substantially reduced.

FIG. 5 illustrates the transistor 100 at a later stage of manufacturing. A substrate 510 has a nitrogen-doped electrode 520 formed thereover, with a gate dielectric 530 formed therebetween. In some cases, the nitrogen-doped electrode 520 may include polysilicon. The illustrated nitrogen-doped electrode 520 also includes a grain boundary 540 passivated by the implanting of nitrogen into the gate electrode layer 330. Gate sidewall spacers 550 are located over source/drain regions 560.

In one embodiment, a source/drain implant process 570 implants nitrogen and a source/drain dopant into the source/drain regions 560 and the nitrogen-doped electrode 520. In some embodiments, nitrogen is optionally implanted before the source/drain dopant. As described previously, implanting of nitrogen into the source/drain regions 560 may reduce dislocations therein that might otherwise form after implantation of the source/drain dopant. In some embodiments, the nitrogen concentration in the nitrogen-doped electrode 520 is greater than the concentration of the source/drain dopant therein. When the transistor 300 is nMOS, the source/drain dopant is an n-type dopant such as, e.g., As or P. When the transistor 300 is pMOS, the source/drain dopant is a p-type dopant such as, e.g., B.

In one aspect, the targeted concentration of nitrogen in the source/drain regions 560 depends on the concentration of the source/drain dopant therein. In an advantageous embodiment, the nitrogen dose is limited to about a minimum necessary to suppress the formation of source/drain dislocations. For example, when the dose of As in the source/drain regions 560 is about 2E15 cm⁻², a minimum dose of nitrogen in the source/drain regions may be about one tenth the source/drain dose, or about 2E14 cm⁻². In some cases, the nitrogen dose in the source/drain regions 560 may be greater than the minimum necessary to suppress dislocations. In one embodiment, the nitrogen dose is about one half of the As dose. When the source/drain regions 560 are formed with an As dose of about 2E15 cm⁻², e.g., a preferred nitrogen dose in the source/drain regions 560 is about 1E15 cm⁻².

Because nitrogen was implanted into the gate electrode layer 310, and the nitrogen-doped electrode 520 is exposed during the implant process 570, the nitrogen-doped electrode 520 has a greater concentration of nitrogen therein than do the source/drain regions 560. In some embodiments, the dose of nitrogen delivered to the nitrogen-doped electrode 520, including nitrogen implanted into the gate electrode layer 330, is at least equal to the source/drain dopant dose implanted into the nitrogen-doped electrode 520. In some cases, the total nitrogen dose may be twice the source/drain dopant dose or greater. In an advantageous embodiment, the nitrogen dose is at least 1.5 times the source/drain dopant dose.

In a nonlimiting example, a nitrogen dose of about 2E15 cm⁻² is implanted into the gate electrode layer 330 by the implant process 340. An additional nitrogen dose of about 1E15 cm⁻² is implanted into the nitrogen-doped electrode 520 by the source/drain implant process 570. A dose of about 2E15 cm⁻² of As is implanted into the nitrogen-doped electrode 520 by the source/drain implant process 570. Thus, the total nitrogen dose delivered to the nitrogen-doped electrode 520 is about 3E15 cm⁻², or 1.5 times the As dose delivered to the nitrogen-doped electrode 520. When the nitrogen-doped electrode 520 is about 120 nm thick, this dose results in a concentration of nitrogen in the nitrogen-doped electrode 520 of about 1.7E22 cm⁻³, or about 2.8%.

If the concentration of nitrogen in the nitrogen-doped electrode 520 is too high, then the parasitic resistance of the electrode may become undesirably high. The permitted upper limit of the parasitic resistance will be determined in general by the tolerance thereto of the device design. In some cases, the upper limit on the nitrogen doping of the nitrogen-doped electrode 520 is about 2-3 times the source/drain dopant concentration in the nitrogen-doped electrode 520. In other cases, the upper limit is about 5E21 cm⁻³.

Experimental data show a dramatic and unexpected benefit provided by the invention. In one experiment, several wafers from a manufacturing lot were processed using an As dose of about 2E15 cm⁻² and a nitrogen dose of about 1E15 cm⁻² in the source/drain regions of nMOS transistors. One half of these wafers were additionally processed to implant molecular nitrogen at 16 keV to a dose of about 1E15 cm⁻² into the gate dielectric layer before forming the gate electrodes. After completion of all processing, individual integrated circuits were separated and packaged. Post burn-in Vₘᵢₙ drift was eliminated in the group processed with the gate electrode layer nitrogen implant, resulting in 17% greater yield. All other relevant electrical parametrics were unchanged, indicating good compatibility of the nitrogen implant with overall device performance.

While the transistor 300 may be an nMOS or a pMOS transistor, in some cases greater utility of the invention may be obtained for nMOS transistors. Boron, commonly used as the p-type dopant, is thought to diffuse more easily in the nitrogen-doped electrode 520 by lattice diffusion than do n-type dopants such as As and P. In one embodiment, only nMOS transistors are formed including the nitrogen implant to the gate electrodes. In such cases, PMOS transistors may be masked off using conventional masking techniques.

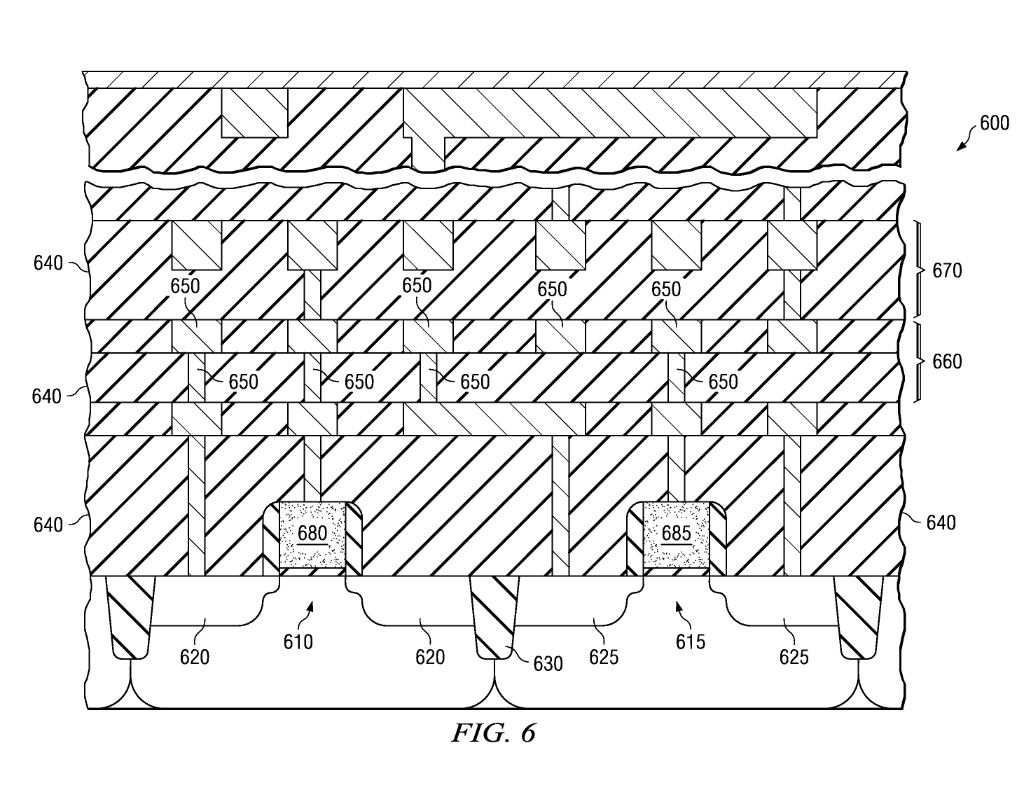

FIG. 6 illustrates a sectional view of a semiconductor device 600 formed according to the invention. The device 600 includes an nMOS transistor 610 and a pMOS transistor 615. The transistors 610, 615 include source/drain regions 620, 625 and are isolated by isolation structures 630. Dielectric layers 640 are formed over the transistors 610, 615, and interconnects 650 are formed therein. The interconnects 650 may be formed using a single damascene 660 or a dual damascene 670 architecture. The interconnects 650 are configured to connect the transistors to other circuit components, including other transistors operating at a same or different voltage supply or gate voltage. Other circuit components may include, without limitation, MOS or bipolar transistors, optical devices and interconnects, diodes, and capacitors. The device 600 may include any number of interconnect levels called for by the design of the device 600.

The nMOS transistor 610 is formed according to the invention described herein. In particular, forming the nMOS transistor 610 includes implanting nitrogen into a gate electrode 680 as described by the process 340. The gate electrode 680 includes a greater concentration of nitrogen than the source/drain regions 620. The concentration of nitrogen in the gate electrode 680 is also greater than the concentration of an n-type dopant in the gate electrode 680. The pMOS transistor 615 may also be formed according to the invention. In this case, a gate electrode 685 includes a greater concentration of nitrogen than the source/drain regions 625. The concentration of nitrogen in the gate electrode 685 may also be greater than the concentration of a p-type dopant in the gate electrode 685.

Those skilled in the art will appreciate that other and further additions, deletions, substitutions and modifications may be made to the described embodiments without departing from the scope the disclosure set forth herein.

What is claimed is:

1. A semiconductor device comprising:
source/drain regions formed in a substrate and having a concentration of nitrogen of at least about 5E18 cm⁻³;
a gate dielectric located over said substrate and between said source/drain regions;
gate sidewall spacers located over said source/drain regions; and
a nitrogen-doped electrode comprising polysilicon and located over said gate dielectric, said electrode having a concentration of nitrogen therein greater than said concentration of nitrogen in said source/drain regions.

2. The semiconductor device recited in claim 1, wherein said electrode further comprises a source/drain dopant, and said concentration of nitrogen in said gate is at least about 1.5 times a concentration of said source/drain dopant in said gate.

3. The semiconductor device recited in claim 2, wherein said source/drain dopant is As or P.

4. The semiconductor device recited in claim 2, wherein said average source/drain dopant concentration is about 1.7E22 cm⁻³ and said concentration in said gate electrode is about 2.5E22 cm⁻³.

5. The semiconductor device recited in claim 1, wherein said concentration of nitrogen in said gate electrode is at least about two times said concentration of nitrogen in said source/drain.

6. The semiconductor device recited in claim 1, further comprising a plurality of dielectric layers and metal conductors configured to provide a conductive path therethrough, said conductors connecting said gate and source/drain regions to a terminal of passive or other active devices on said substrate.

7. The semiconductor device recited in claim 1, wherein said semiconductor device is an nMOS FET.

8. A field effect transistor, comprising:
source/drain regions formed in a substrate and having a concentration of nitrogen of at least about 5E18 cm⁻³;
a gate dielectric located over said substrate and between said source/drain regions;
gate sidewall spacers located over said source/drain regions; and
a gate electrode comprising polysilicon and an n-type dopant located over said gate dielectric, said electrode having a concentration of nitrogen therein greater than both a concentration of said n-type dopant in said electrode and said average nitrogen concentration in said source/drain.

9. The field effect transistor recited in claim 8, wherein said n-type dopant comprises As or P, and said concentration of nitrogen in said electrode is at least about 1.5 times a concentration of said n-type dopant in said electrode.

10. The field effect transistor recited in claim 8, wherein said concentration of said n-type dopant in said electrode is about 1.7E22 cm⁻³ and said concentration of nitrogen in said electrode is about 2.5E22 cm⁻³.

11. The field effect transistor recited in claim 8, wherein said concentration of nitrogen in said gate electrode is at least about 1.5 times said concentration of nitrogen in said source/drain.

12. The field effect transistor recited in claim 8, wherein said gate electrode is a nitrided silicon oxide with a thickness of about 1.2 nm or less.

13. The field effect transistor recited in claim 8, wherein said transistor is an nMOS FET.

14. A method of manufacturing a semiconductor device, comprising:
forming source/drain regions in a substrate;
forming a gate dielectric layer over said substrate;
depositing a polysilicon layer over said gate dielectric layer;
doping said polysilicon layer with an n-type dopant;
doping said polysilicon layer with nitrogen;
removing a portion of said polysilicon layer to form a gate electrode between said source/drain regions; and
doping said source/drain regions and said electrode with nitrogen.

15. The method recited in claim 14, wherein said n-type dopant comprises As and said polysilicon layer is doped with an As dose of about 2E15 cm⁻², and doped with a nitrogen dose of about 3E15 cm⁻² or greater.

16. The method recited in claim 14, wherein said gate electrode has a thickness of about 120 nm and said nitrogen is implanted as a diatomic species at about 30 keV or a monatomic species at about 15 keV.

17. The method recited in claim 14, wherein said n-type dopant is implanted before said nitrogen.

18. The method recited in claim 14, wherein said gate electrode is doped with nitrogen to a concentration ranging from about 100% to about 200% of a concentration of said n-type dopant.

19. The method recited in claim 18, wherein said polysilicon layer is doped with nitrogen to a concentration ranging from about 50% to about 100% of a concentration of said n-type dopant.

20. The method recited in claim 14, further comprising forming a plurality of dielectric layers over said gate electrode and conductors therein, said conductors connecting said gate and source/drain regions to a terminal of passive or other active devices on said substrate.
